(19) United States
(12) Patent Application Publication
(10) Pub. No.: US 2023/0417836 A1
(43) Pub. Date: Dec. 28, 2023

(54) DETECTION SYSTEM FOR ESTIMATING STATE OF BATTERY DEVICE AND OPERATING METHOD THEREOF

(71) Applicant: AMIDAS Energy CO., LTD., Taipei City (TW)

(72) Inventor: Chin Sheng Wang, New Taipei City (TW)

(73) Assignee: AMIDAS Energy CO., LTD., Taipei City (TW)

(21) Appl. No.: 17/884,571

(22) Filed: Aug. 10, 2022

(30) Foreign Application Priority Data
Jun. 23, 2022 (TW) 111123345

(51) Int. Cl. G01R 31/387; G01R 31/3835; G01R 31/374; G01R 31/392

(52) U.S. Cl. CPC G01R 31/387; G01R 31/3835; G01R 31/374; G01R 31/392

(57) ABSTRACT

A detection system and an operating method are provided. The detection system is used to estimate a degradation state of a battery device. The detection system includes a first operation circuit, a second operation circuit, and a processor. The first operation circuit receives voltage timing data of the battery device, and calculates a first reference value of the battery device according to the voltage timing data. The second operation circuit receives temperature timing data of the battery device, and calculates a second reference value of the battery device according to the temperature timing data. The processor provides state data related to the degradation state according to the first reference value and the second reference value.

### CROSS-REFERENCE TO RELATED APPLICATION

This application claims the priority benefit of Taiwan application serial no. 111123345, filed on Jun. 23, 2022. The entirety of the above-mentioned patent application is hereby incorporated by reference herein and made a part of this specification.

### BACKGROUND

### Technical Field

The disclosure relates to a detection system and an operating method for operating the detection system, and more particularly to a detection system for estimating a state of a battery device and an operating method for operating the detection system.

### Description of Related Art

The battery device is widely used in various aspects of daily life, such as vehicle charging piles, community power grids, vehicle batteries, and energy storage cabinets. Under long-term use, the performance, the state of charge (SOC), and the security of the battery device will gradually degrade. Once the lifetime of the battery device reaches the end, the battery device may not be able to supply power or may even catch fire and burn. If the degradation state of the battery device can be predicted, the administrator can retire the battery device before the end of the lifetime, thereby avoiding cases such as power failure or catching fire and burning. As such, it can be seen that how to establish an estimation mechanism for estimating the degradation state of the battery device is one of the research focuses of persons skilled in the art.

### SUMMARY

The disclosure provides a detection system and an operating method for estimating a degradation state of a battery device.

A detection system of the disclosure is used to estimate a degradation state of a battery device. The detection system includes a first operation circuit, a second operation circuit, and a processor. The first operation circuit receives voltage timing data of the battery device, and calculates a first reference value of the battery device according to the voltage timing data. The voltage timing data includes timing data of the battery device in multiple discharge-charge cycles. The second operation circuit receives temperature timing data of the battery device, and calculates a second reference value of the battery device according to the temperature timing data. The temperature timing data includes a temperature trend of the battery device in the discharge-charge cycles. The processor is coupled to the first operation circuit and the second operation circuit. The processor receives the first reference value and the second reference value, and provides state data related to the degradation state according to the first reference value and the second reference value.

An operating method of the disclosure is used to operate a detection system. The detection system is used to estimate a degradation state of a battery device. The detection system includes a first operation circuit, a second operation circuit, and a processor. The operating method includes the following steps. Voltage timing data of the battery device is received by the first operation circuit, and a first reference value of the battery device is calculated according to the voltage timing data. The voltage timing data includes timing data of the battery device in multiple discharge-charge cycles. Temperature timing data of the battery device is received by the second operation circuit, and a second reference value of the battery device is calculated according to the temperature timing data. The temperature timing data includes a temperature trend of the battery device in the discharge-charge cycles. State data related to the degradation state is provided by the processor according to the first reference value and the second reference value.

Based on the above, the detection system and the operating method of the disclosure calculate the first reference value of the battery device according to the voltage timing data, calculate the second reference value of the battery device according to the temperature timing data, and provide the state data according to the first reference value and the second reference value. It should be noted that the voltage timing data is related to the variation trend of the state of charge (SOC) of the discharge-charge cycles. The temperature timing data is related to the temperature trend of the discharge-charge cycles. Therefore, the state data is related to the degradation state of the battery device. In this way, the degradation state of the battery device can be estimated according to the state data.

In order for the features and advantages of the disclosure to be more comprehensible, the following specific embodiments are described in detail in conjunction with the drawings.

### BRIEF DESCRIPTION OF THE DRAWINGS

FIG. 1 is a schematic diagram of a detection system according to a first embodiment of the disclosure.

FIG. 2 is a schematic diagram of voltage timing data according to an embodiment of the disclosure.

FIG. 3 is a schematic diagram of temperature timing data according to an embodiment of the disclosure.

FIG. 4 is a flowchart of an operating method according to the first embodiment of the disclosure.

FIG. 5 is a schematic diagram of a detection system according to a second embodiment of the disclosure.

FIG. 6 is a flowchart of an operating method according to the second embodiment of the disclosure.

### DETAILED DESCRIPTION OF DISCLOSED EMBODIMENTS

Some embodiments of the disclosure will be described in detail below with reference to the drawings. For reference numerals quoted in the following description, when the same reference numerals appear in different drawings, the reference numerals will be regarded as referring to the same or similar elements. The embodiments are only a part of the disclosure and do not disclose all possible implementations of the disclosure. More precisely, the embodiments are only examples within the scope of the claims of the disclosure.

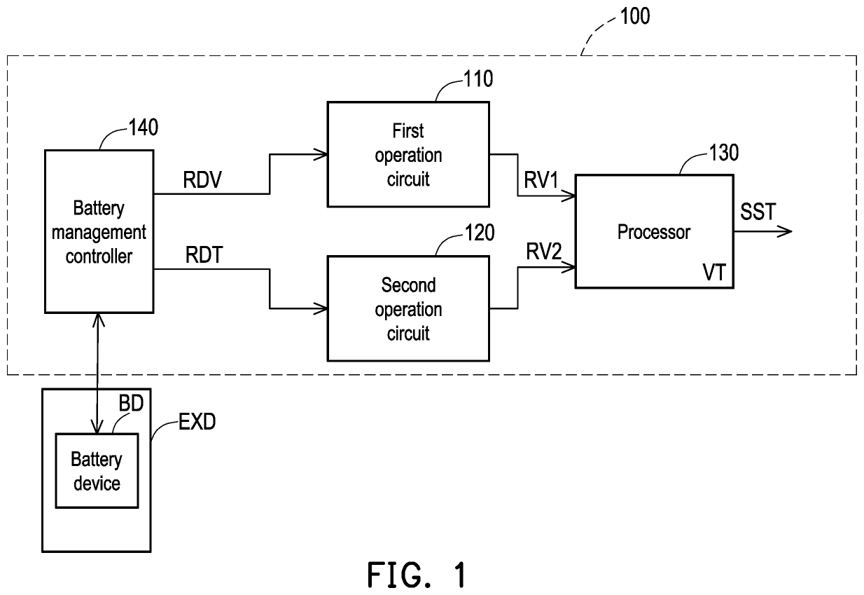

Please refer to FIG. 1. FIG. 1 is a schematic diagram of a detection system according to a first embodiment of the disclosure. In this embodiment, a detection system 100 is used to estimate a degradation state of a battery device BD. The detection system 100 includes a first operation circuit 110, a second operation circuit 120, and a processor 130. The first operation circuit 110 receives voltage timing data RDV of the battery device BD. In this embodiment, the voltage timing data RDV includes timing data of the battery device BD in multiple discharge-charge cycles. The voltage timing data RDV is, for example, voltage raw data in the discharge-charge cycles. The first operation circuit 110 calculates a first reference value RV1 of the battery device BD according to the voltage timing data RDV. The second operation circuit 120 receives temperature timing data RDT of the battery device BD. In this embodiment, the temperature timing data RDT includes a temperature trend of the battery device BD in the discharge-charge cycles. The temperature timing data RDT is, for example, temperature raw data in the discharge-charge cycles. The second operation circuit 120 calculates a second reference value RV2 of the battery device BD according to the temperature timing data RDT.

In this embodiment, the processor 130 is coupled to the first operation circuit 110 and the second operation circuit 120. The processor 130 receives the first reference value RV1 and the second reference value RV2, and provides state data SST related to the degradation state of the battery device BD according to the first reference value RV1 and the second reference value RV2.

It is worth mentioning here that the first operation circuit 110 calculates the first reference value RV1 of the battery device BD according to the voltage timing data RDV. The second operation circuit 120 calculates the second reference value RV2 of the battery device BD according to the temperature timing data RDT. The processor 130 provides the state data SST according to the first reference value RV1 and the second reference value RV2. The voltage timing data RDV is related to the variation trend of the state of charge (SOC) of the discharge-charge cycles. The temperature timing data RDT is related to the temperature trend of the discharge-charge cycles. The variation trend of the SOC and the temperature trend are related to the degradation of electrochemical energy and/or the electrical aging inside the battery device BD. Therefore, the state data SST is related to the degradation state of the battery device BD. In this way, the degradation state of the battery device BD can be estimated according to the state data SST.

In this embodiment, the battery device BD is disposed in an external device EXD. For example, the external device EXD may be a device such as an energy storage cabinet or a charging pile, but the disclosure is not limited thereto. The battery device BD is, for example, a high-voltage lithium battery module, but the disclosure is not limited thereto. The battery device BD includes at least one battery unit.

In this embodiment, the first operation circuit 110, the second operation circuit 120, and the processor 130 may respectively be, for example, an artificial neural network, an artificial intelligence model, a central processing unit (CPU), other programmable general-purpose or specific-purpose microprocessors, digital signal processors (DSPs), programmable controllers, application specific integrated circuits (ASICs), programmable logic devices (PLDs), other similar devices, or a combination of the devices that can load and execute a computer program.

In this embodiment, the detection system 100 further includes a battery management controller (BMC) 140. The battery management controller 140 communicates with the external device EXD to receive the voltage timing data RDV and the temperature timing data RDT of the battery device BD. The battery management controller 140 transmits the voltage timing data RDV to the first operation circuit 110 and transmits the temperature timing data RDT to the second operation circuit 120. Further, the battery management controller 140 can perform wired communication or wireless communication with the external device EXD to collect the voltage timing data RDV and the temperature timing data RDT of the battery device BD in real time, transmit the voltage timing data RDV to the first operation circuit 110, and transmit the temperature timing data RDT to the second operation circuit 120. Therefore, the detection system 100 can estimate the degradation state of the battery device BD in real time.

In addition, the battery management controller 140 can also communicate with other multiple external devices to collect the voltage timing data RDV and the temperature timing data RDT of multiple battery devices of the external devices in real time. In other words, the detection system 100 can estimate and monitor the degradation states of multiple battery devices in real time, and even estimate and monitor the degradation states of multiple battery devices in multiple locations around the world.

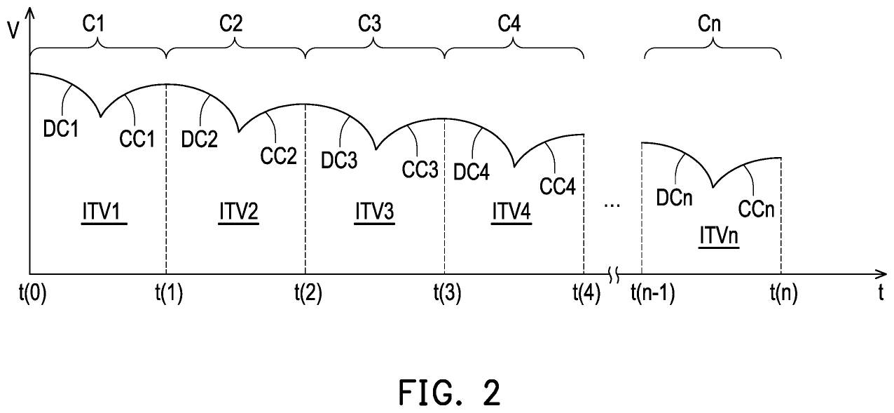

The implementation details of the first operation circuit 110 calculating the first reference value RV1 will be described below. Please refer to FIG. 1 and FIG. 2 at the same time. FIG. 2 is a schematic diagram of voltage timing data according to an embodiment of the disclosure. FIG. 2 illustrates the voltage timing data RDV of the battery device BD in discharge-charge cycles C1 to Cn. The initial discharge-charge cycle C1 is performed between a time point t(0) and a time point t(1). The voltage timing data in the discharge-charge cycle C1 includes discharge data DC1 and charge data CC1. The discharge data DC1 and the charge data CC1 are respectively timings of voltage values. When the discharge-charge cycle C1 ends, the first operation circuit 110 performs an integral operation on a voltage value of the discharge-charge cycle C1 based on time to generate an integral value ITV1 (that is, an initial integral value). In other words, the first operation circuit 110 performs the integral operation on the voltage value of the initial cycle (that is, the discharge-charge cycle C1) among the discharge-charge cycles C1 to Cn based on time to generate the initial integral value.

The discharge-charge cycle C2 is performed between the time point t(1) and a time point t(2). The voltage timing data in the discharge-charge cycle C2 includes discharge data DC2 and charge data CC2. When the discharge-charge cycle C2 ends, the first operation circuit 110 performs an integral operation on a voltage value of the discharge-charge cycle C2 based on time to generate an integral value ITV2. At the time point t(2), the integral value ITV2 is a current integral value. The first operation circuit 110 calculates the first reference value RV1 according to the reduction amount of the integral value ITV2 (that is, the current integral value) relative to the integral value ITV1 (that is, the initial integral value) after the time point t(2).

The discharge-charge cycle C3 is performed between the time point t(2) and a time point t(3). The voltage timing data in the discharge-charge cycle C3 includes discharge data DC3 and charge data CC3. When the discharge-charge cycle C3 ends, the first operation circuit 110 performs an integral operation on a voltage value of the discharge-charge cycle C3 based on time to generate an integral value ITV3. At the time point t(3), the integral value ITV3 is a current integral value. The first operation circuit 110 calculates the first reference value RV1 according to the reduction amount of the integral value ITV3 (that is, the current integral value) relative to the integral value ITV1 after the time point t(3).

The discharge-charge cycle C4 is performed between the time point t(3) and a time point t(4). The voltage timing data in the discharge-charge cycle C4 includes discharge data DC4 and charge data CC4. When the discharge-charge cycle C4 ends, the first operation circuit 110 performs an integral operation on a voltage value of the discharge-charge cycle C4 based on time to generate an integral value ITV4. At the time point t(4), the integral value ITV4 is a current integral value. The first operation circuit 110 calculates the first reference value RV1 according to the reduction amount of the integral value ITV4 (that is, the current integral value) relative to the integral value ITV1 after the time point t(4).

The discharge-charge cycle Cn is performed between a time point t(n−1) and a time point t(n). The voltage timing data in the discharge-charge cycle Cn includes discharge data DCn and charge data CCn. When the discharge-charge cycle Cn ends, the first operation circuit 110 performs an integral operation on a voltage value of the discharge-charge cycle Cn based on time to generate an integral value ITVn. At the time point t(n), the integral value ITVn is a current integral value. The first operation circuit 110 calculates the first reference value RV1 according to the reduction amount of the integral value ITVn (that is, the current integral value) relative to the integral value ITV1 after the time point t(n).

Here, for example, the integral value ITV2 is reduced by 5% relative to the integral value ITV1. Therefore, the first operation circuit 110 calculates that the first reference value RV1 is equal to “5”. The integral value ITV3 is reduced by 8% relative to the integral value ITV1. Therefore, the first operation circuit 110 calculates that the first reference value RV1 is equal to “8”. The integral value ITV4 is reduced by 10% relative to the integral value ITV1. Therefore, the first operation circuit 110 calculates that the first reference value RV1 is equal to “10”. The integral value ITVn is reduced by 80% relative to the integral value ITV1. Therefore, the first operation circuit 110 calculates that the first reference value RV1 is equal to “80”. The first reference value RV1 is positively correlated with the reduction amount.

In this embodiment, the discharge-charge cycles C1 to Cn are substantially the same. The discharge time lengths of the discharge-charge cycles C1 to Cn are the same as each other. The charge time lengths of the discharge-charge cycles C1 to Cn are also the same as each other. For example, depending on the actual application, the time length of each of the discharge-charge cycles C1 to Cn may be several hours or a day. Each discharge time length is, for example, several hours. Each charge time length is, for example, several hours, but the disclosure is not limited thereto. Depending on the actual application, the discharge time length may be the same as or different from the charge time length.

Depending on actual usage requirements, the waveforms of the discharge data DC1 to DCn and the charge data CC1 to CCn may change. The waveforms of the discharge data DC1 to DCn and the charge data CC1 to CCn of the disclosure are not limited to this embodiment.

In this embodiment, the first reference value RV1 can reflect the degradation condition of the SOC of the battery device BD in the discharge-charge cycles C1 to Cn. The greater the first reference value RV1, the more severe the degradation condition of the SOC of the battery device BD.

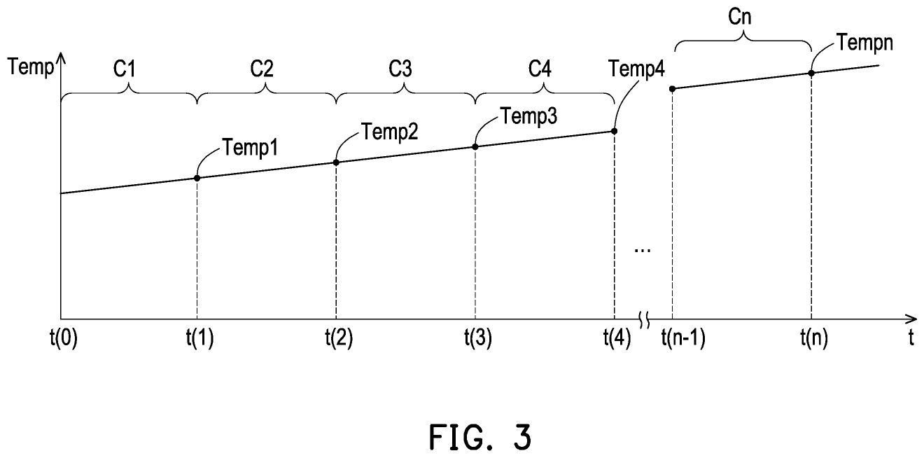

The implementation details of the second operation circuit 120 calculating the first reference value RV2 will be described below. Please refer to FIG. 1 and FIG. 3 at the same time. FIG. 3 is a schematic diagram of temperature timing data according to an embodiment of the disclosure. The temperature timing data RDT includes the temperature trend of the battery device BD in the discharge-charge cycles C1 to Cn. When the initial discharge-charge cycle C1 ends, the second operation circuit 120 obtains a temperature value Temp1 (that is, an initial temperature value) of the battery device BD at the time point t(1). When the discharge-charge cycle C2 ends, the second operation circuit 120 obtains a temperature value Temp2 of the battery device BD at the time point t(2). The second operation circuit 120 calculates the second reference value RV2 according to the amount of increase of the temperature value Temp2 (that is, a current temperature value) relative to the temperature value Temp1 (that is, the initial temperature value) after the time point t(2).

When the discharge-charge cycle C3 ends, the second operation circuit 120 obtains a temperature value Temp3 of the battery device BD at the time point t(3). The second operation circuit 120 calculates the second reference value RV2 according to the amount of increase of the temperature value Temp3 (that is, a current temperature value) relative to the temperature value Temp1 after the time point t(3).

When the discharge-charge cycle C4 ends, the second operation circuit 120 obtains a temperature value Temp4 of the battery device BD at the time point t(4). The second operation circuit 120 calculates the second reference value RV2 according to the amount of increase of the temperature value Temp4 (that is, a current temperature value) relative to the temperature value Temp1 after the time point t(4).

When the discharge-charge cycle Cn ends, the second operation circuit 120 obtains a temperature value Tempn of the battery device BD at the time point t(n). The second operation circuit 120 calculates the second reference value RV2 according to the amount of increase of the temperature value Tempn (that is, a current temperature value) relative to the temperature value Temp1 after the time point t(n).

Here, for example, the temperature value Temp2 is increased by 3° C. relative to the temperature value Temp1. Therefore, the second operation circuit 120 calculates that the second reference value RV2 is equal to “6”. The temperature value Temp3 is increased by 6° C. relative to the temperature value Temp1. Therefore, the second operation circuit 120 calculates that the second reference value RV2 is equal to “12”. The temperature value Temp4 is increased by 9° C. relative to the temperature value Temp1. Therefore, the second operation circuit 120 calculates that the second reference value RV2 is equal to “18”. The temperature value Tempn is increased by 50° C. relative to the temperature value Temp1. Therefore, the second operation circuit 120 calculates that the second reference value RV2 is equal to “100”. The second reference value RV2 is positively correlated with the amount of increase.

In this embodiment, the second reference value RV2 can reflect the temperature rising trend of the battery device BD in the discharge-charge cycles C1 to Cn. The greater the second reference value RV2, the more severe the temperature rising condition of the battery device BD. The temperature rising condition may reflect poor or rapid aging of the circuit design, the structural design, or the heat dissipation design of the battery device BD, such as a design error or the battery device BD being collided or damaged. In this embodiment, the greater the second reference value RV2, the greater the risk of the battery device BD catching fire and burning.

Please refer to FIG. 1, FIG. 2, and FIG. 3 at the same time. Based on the teachings of the foregoing embodiments, the higher at least one of the first reference value RV1 and the second reference value RV2, the more severe the degradation state of the battery device BD estimated by the processor 130. Therefore, the state data SST indicates relevant information of a severe degradation state of the battery device BD. On the other hand, when the first reference value RV1 and the second reference value RV2 are both relatively low, the processor 130 estimates that the degradation state of the battery device BD is relatively slight. Therefore, the state data SST indicates relevant information of a slight degradation state of the battery device BD.

In this embodiment, the first reference value RV1 and the second reference value RV2 may be regarded as the age of the battery device BD. The greater the first reference value RV1 and the second reference value RV2, the older the battery device BD. The smaller the first reference value RV1 and the second reference value RV2, the younger the battery device BD.

In this embodiment, a threshold value VT may be set. When one of the first reference value RV1 and the second reference value RV2 is greater than the threshold value, the state data SST provided by the processor 130 includes deactivation information corresponding to the battery device BD. The deactivation information indicates that the battery device BD is no longer available for the external device EXD. In some embodiments, the deactivation information deactivates a notification signal of the battery device BD.

For example, the threshold value VT is “90”. When the discharge-charge cycle Cn ends, the first reference value RV1 is equal to “80” and the second reference value RV2 is equal to “100”. The processor 130 judges that the second reference value RV2 is greater than the threshold value VT, which means that the temperature rising condition of the battery device BD is obviously abnormal, and there may be a risk of catching fire and burning. Therefore, the state data SST includes the deactivation information corresponding to the battery device BD.

For example, the threshold value VT is “90”. The first reference value RV1 is equal to “95” and the second reference value RV2 is equal to “80”. The processor 130 judges that the first reference value RV1 is greater than the threshold value VT, which means that the degradation condition of the SOC of the battery device BD is very severe. Therefore, the state data SST includes the deactivation information. For example, the threshold value VT is “90”. The first reference value RV1 is equal to “95” and the second reference value RV2 is equal to “95”. The processor 130 judges that the first reference value RV1 and the second reference value RV2 are both greater than the threshold value VT. Therefore, the state data SST includes the deactivation information.

For example, the threshold value VT is “90”. The first reference value RV1 is equal to “40” and the second reference value RV2 is equal to “60”. The processor 130 judges that the first reference value RV1 and the second reference value RV2 are both smaller than the threshold value VT. Therefore, the state data SST does not include the deactivation information.

It should be noted that the first reference value RV1 is a relative value related to an integral value. The second reference value RV2 is a relative value related to a temperature value. Therefore, the detection system 100 is suitable for estimating the degradation state of the battery device BD having a single battery unit or the degradation state of the battery device BD having multiple battery units coupled in series.

In addition, it should also be noted that the processor 130 can learn the variation trends of the first reference value RV1 and the second reference value RV2. Based on specific usage requirements, in the case where the battery device BD has undergone the discharge-charge cycles, the processor 130 can determine the rising variation trends of the first reference value RV1 and the second reference value RV2, and estimate time points when the first reference value RV1 and the second reference value RV2 reach the threshold value VT based on the rising variation trends. In other words, the processor 130 can estimate the lifetime of the battery device BD based on the variation trends of the first reference value RV1 and the second reference value RV2.

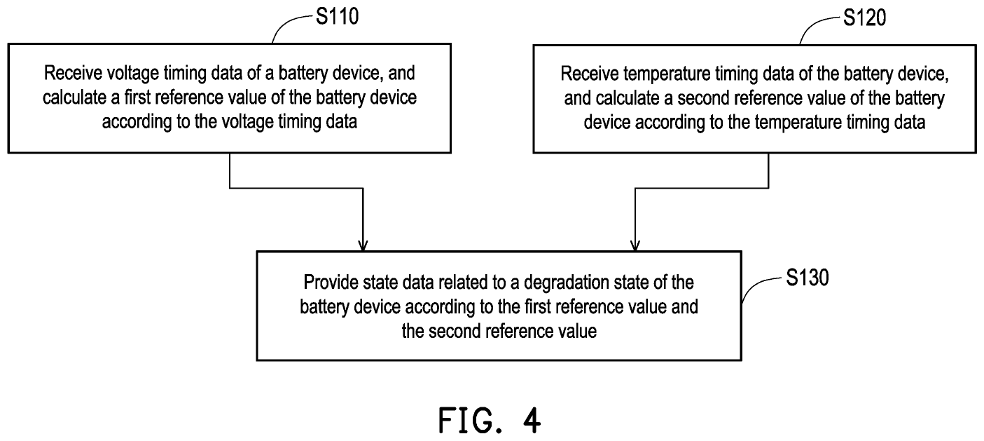

Please refer to FIG. 1 and FIG. 4 at the same time. FIG. 4 is a flowchart of an operating method according to the first embodiment of the disclosure. The detection system 100 may be operated according to the operating method. In this embodiment, the operating method includes Steps S110 to S130. In Step S110, the first operation circuit 110 receives the voltage timing data RDV of the battery device BD, and calculates the first reference value RV1 of the battery device BD according to the voltage timing data RDV. In Step S120, the second operation circuit 120 receives the temperature timing data RDT of the battery device BD, and calculates the second reference value RV2 of the battery device BD according to the temperature timing data RDT. In Step S130, the processor 130 provides the state data SST related to the degradation state of the battery device BD according to the first reference value RV1 and the second reference value RV2. The implementation details of Steps S110 to S130 have been fully described in the embodiments of FIG. 1 to FIG. 3, so there will be no repetition.

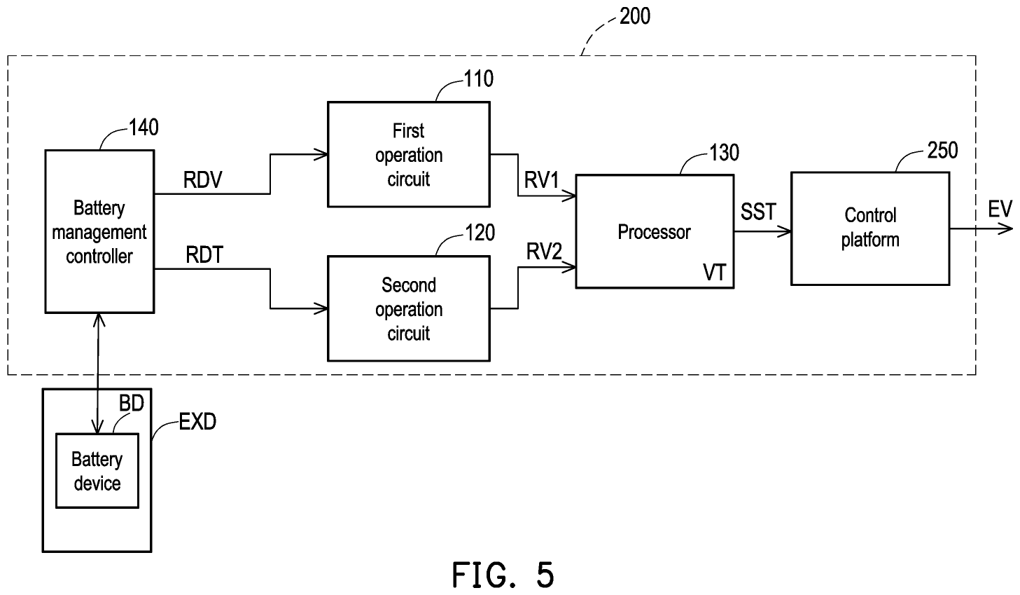

Please refer to FIG. 5. FIG. 5 is a schematic diagram of a detection system according to a second embodiment of the disclosure. In this embodiment, a detection system 200 includes a first operation circuit 110, a second operation circuit 120, a processor 130, a battery management controller 140, and a control platform 250. The implementation details of the first operation circuit 110, the second operation circuit 120, the processor 130, and the battery management controller 140 have been fully described in the embodiments of FIG. 1 to FIG. 3, so there will be no repetition.

In this embodiment, the control platform 250 communicates with the processor 130. The control platform 250 generates evaluation data EV corresponding to the battery device BD according to the state data SST of the battery device BD. The evaluation data EV includes an evaluation score of applying the battery device BD to the external device EXD. In this embodiment, the state data SST at least indicates the relevant information of the severe degradation state or the slight degradation state of the battery device BD. For example, the control platform 250 learns that the battery device BD is in the slight degradation state according to the state data SST. The control platform 250 can learn that the battery device BD is suitable for the external device EXD or the battery device BD has preferred quality and design. Therefore, the control platform 250 increases the evaluation score of the battery device BD. For another example, the control platform 250 learns that the battery device BD is in the severe degradation state according to the state data SST. The control platform 250 can learn that the battery device BD is not suitable for the external device EXD or the design of the battery device BD is poor. Therefore, the control platform 250 reduces the evaluation score of the battery device BD. In other words, the battery device BD with a high evaluation score has a lower first reference value RV1 and a lower second reference value RV2. The battery device BD with a low evaluation score has a higher first reference value RV1 and a higher second reference value RV2. Therefore, the variation in SOC and the variation in temperature of the battery device BD with a low evaluation score are relatively obvious.

In addition, the control platform 250 can also monetize the evaluation score. Further, the control platform 250 converts the evaluation score of the battery device BD into a conventional value of the battery device BD. The higher the evaluation score of the battery device BD, the higher the conventional value of the battery device BD. The lower the evaluation score of the battery device BD, the lower the conventional value of the battery device BD. Therefore, the administrator can intuitively evaluate whether to use such type of the battery device BD according to the conventional value of the battery device BD.

In this embodiment, the control platform 250 can also learn the first reference value RV1 and the second reference value RV2 according to the state data SST. The control platform 250 can provide information related to the trend in SOC of the battery device BD and the trend in temperature of the battery device BD. Therefore, the administrator can obtain the characteristics of such type of the battery device BD according to the information, and provide improvement suggestions, such as optimizing the reliability of the SOC, the circuit design, or parameters of the discharge-charge cycle, of the battery device BD to the manufacturer of the battery device BD accordingly.

In this embodiment, the control platform 250 may be a server, a cloud server, an artificial neural network, an artificial intelligence model, a central processing unit (CPU), other programmable general-purpose or specific-purpose microprocessors, digital signal processors (DSPs), programmable controllers, application specific integrated circuits (ASICs), programmable logic devices (PLDs), other similar devices, or a combination of the devices that can load and execute a computer program.

The battery management controller 140 can also communicate with other multiple external devices to collect the voltage timing data RDV and the temperature timing data RDT of multiple battery devices of the external devices in real time. Therefore, the control platform 250 can generate multiple evaluation data EV corresponding to the battery devices. Therefore, the detection system 200 can estimate and monitor degradation states of the battery devices in real time, and even generate multiple evaluation data EV of multiple battery devices in multiple locations around the world.

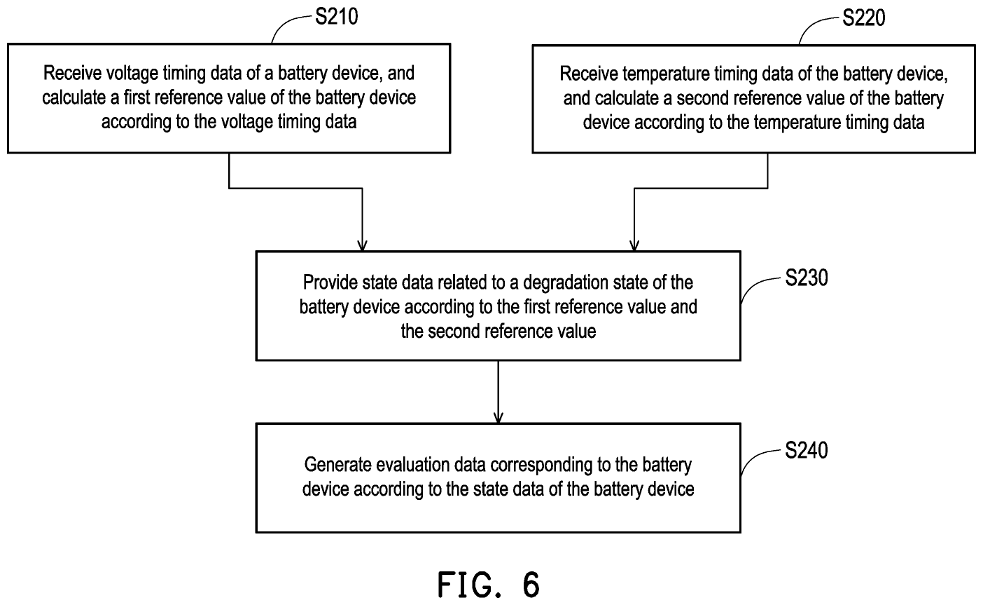

Please refer to FIG. 5 and FIG. 6 at the same time. FIG. 6 is a flowchart of an operating method according to the second embodiment of the disclosure. The detection system 200 may be operated according to the operating method. In this embodiment, the operating method includes Steps S210 to S240. In Step S210, the first operation circuit 110 receives the voltage timing data RDV of the battery device BD, and calculates the first reference value RV1 of the battery device BD according to the voltage timing data RDV. In Step S220, the second operation circuit 120 receives the temperature timing data RDT of the battery device BD, and calculates the second reference value RV2 of the battery device BD according to the temperature timing data RDT. In Step S230, the processor 130 provides the state data SST related to the degradation state of the battery device BD according to the first reference value RV1 and the second reference value RV2. In Step S240, the control platform 250 generates the evaluation data EV corresponding to the battery device BD according to the state data SST of the battery device BD. The implementation details of Steps S210 to S240 have been fully described in the embodiments of FIG. 1 to FIG. 3 and FIG. 5, so there will be no repetition.

In summary, the detection system and the operating method of the disclosure calculate the first reference value of the battery device according to the voltage timing data, calculate the second reference value of the battery device according to the temperature timing data, and provide the state data according to the first reference value and the second reference value. The voltage timing data is related to the variation trend of the SOC of the discharge-charge cycles. The temperature timing data is related to the temperature trend of the discharge-charge cycles. In other words, the state data is related to the degradation state of the battery device. In this way, the degradation state and the lifetime of the battery device can be estimated according to the state data. In addition, the control platform can evaluate the conventional value of the battery device according to the state data.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A detection system for estimating a degradation state of a battery device, comprising:
a first operation circuit, configured to receive voltage timing data of the battery device, and calculate a first reference value of the battery device according to the voltage timing data, wherein the voltage timing data comprises timing data of the battery device in a plurality of discharge-charge cycles;
a second operation circuit, configured to receive temperature timing data of the battery device, and calculate a second reference value of the battery device according to the temperature timing data, wherein the temperature timing data comprises a temperature trend of the battery device in the discharge-charge cycles; and
a processor, coupled to the first operation circuit and the second operation circuit, and configured to receive the first reference value and the second reference value, and provide state data related to the degradation state according to the first reference value and the second reference value.

2. The detection system according to claim 1, wherein the first operation circuit performs an integral operation on a voltage value of an initial cycle among the discharge-charge cycles based on time to generate an initial integral value, performs an integral operation on a voltage value of a current cycle among the discharge-charge cycles based on time to generate a current integral value, and calculates the first reference value according to a reduction amount of the current integral value relative to the initial integral value.

3. The detection system according to claim 2, wherein the first reference value is positively correlated with the reduction amount.

4. The detection system according to claim 1, wherein the second operation circuit obtains an initial temperature value of an initial cycle among the discharge-charge cycles, obtains a current temperature value of a current cycle among the discharge-charge cycles, and calculates the second reference value according to an amount of increase of the current temperature value relative to the initial temperature value.

5. The detection system according to claim 4, wherein the second reference value is positively correlated with the amount of increase.

6. The detection system according to claim 1, wherein the higher at least one of the first reference value and the second reference value, the more severe the degradation state of the battery device estimated by the processor.

7. The detection system according to claim 1, wherein the processor estimates a lifetime of the battery device based on variation trends of the first reference value and the second reference value.

8. The detection system according to claim 1, further comprising:
a control platform, communicating with the processor and configured to generate evaluation data corresponding to the battery device according to the state data of the battery device.

9. The detection system according to claim 1, wherein the battery device is disposed in an external device.

10. The detection system according to claim 9, further comprising:
a battery management controller, configured to communicate with the external device to receive the voltage timing data and the temperature timing data of the battery device, transmit the voltage timing data to the first operation circuit, and transmit the temperature timing data to the second operation circuit.

11. An operating method for operating a detection system, wherein the detection system is used to estimate a degradation state of a battery device and comprises a first operation circuit, a second operation circuit, and a processor, the operating method comprising:
receiving, by the first operation circuit, voltage timing data of the battery device, and calculating a first reference value of the battery device according to the voltage timing data, wherein the voltage timing data comprises timing data of the battery device in a plurality of discharge-charge cycles;
receiving, by the second operation circuit, temperature timing data of the battery device, and calculating a second reference value of the battery device according to the temperature timing data, wherein the temperature timing data comprises a temperature trend of the battery device in the discharge-charge cycles; and
providing, by the processor, state data related to the degradation state according to the first reference value and the second reference value.

12. The operating method according to claim 11, wherein the step of calculating the first reference value of the battery device according to the voltage timing data comprises:
performing an integral operation on a voltage value of an initial cycle among the discharge-charge cycles based on time to generate an initial integral value;
performing an integral operation on a voltage value of a current cycle among the discharge-charge cycles based on time to generate a current integral value; and
calculating the first reference value according to a reduction amount of the current integral value relative to the initial integral value.

13. The operating method according to claim 12, wherein the first reference value is positively correlated with the reduction amount.

14. The operating method according to claim 11, wherein the step of calculating the second reference value of the battery device according to the temperature timing data comprises:
obtaining an initial temperature value of an initial cycle among the discharge-charge cycles;
obtaining a current temperature value of a current cycle among the discharge-charge cycles; and
calculating the second reference value according to an amount of increase of the current temperature value relative to the initial temperature value.

15. The operating method according to claim 14, wherein the second reference value is positively correlated with the amount of increase.

16. The operating method according to claim 11, wherein the higher at least one of the first reference value and the second reference value, the more severe the estimated degradation state of the battery device.

17. The operating method according to claim 11, further comprising:
estimating a lifetime of the battery device based on variation trends of the first reference value and the second reference value.

18. The operating method according to claim 11, further comprising:
generating evaluation data corresponding to the battery device according to the state data of the battery device.
